(19) United States
(12) Patent Application Publication
(10) Pub. No.: US 2025/0366234 A1
(43) Pub. Date: Nov. 27, 2025

(54) SEMICONDUCTOR IMAGE SENSOR PACKAGE AND METHODS OF PRODUCING

(71) Applicant: SEMICONDUCTOR COMPONENTS INDUSTRIES, LLC, Scottsdale, AZ (US)

(72) Inventor: Weng-Jin WU, Hsinchu City (TW)

(73) Assignee: SEMICONDUCTOR COMPONENTS INDUSTRIES, LLC, Scottsdale, AZ (US)

(21) Appl. No.: 18/671,614

(22) Filed: May 22, 2024

(51) Int. Cl. H01L 27/146

(52) U.S. Cl. CPC H10F 39/804; H10F 39/011; H10F 39/811

(57) ABSTRACT

In a general aspect, a semiconductor package includes a semiconductor die having an image sensor disposed on a first surface. The package further includes a signal redistribution layer disposed on a second surface of the semiconductor die that is opposite the first surface. The package also includes at least one via extending through the semiconductor die from the first surface to the second surface, where a via of the at least one via electrically connects a signal trace on the first surface of the semiconductor die with the signal redistribution layer. The package also includes a glass cover coupled with a portion of the first surface of the semiconductor die via an attachment dam. The portion of the first surface excluding the image sensor, and the attachment dam and the glass cover define a sidewall that is orthogonal to the first surface of the semiconductor die.

### BACKGROUND

Image sensor devices, such as complementary metal-oxide-semiconductor (CMOS) image sensors, are used in a number of applications, such as in cameras for consumer, industrial and automotive applications. However, packages used for prior image sensor devices, such as ball-grid array packages, have a number of drawbacks. For instance, prior packages may be susceptible to reliability issues in certain application environments, such as damage from moisture in automotive and/or industrial applications. Further, an area of a semiconductor die including an image sensor (e.g., a non-optically active area or so called Keep Out Zone (KOZ)) that is used for attaching a protective, e.g., glass, cover to the semiconductor die can increase overall die size, reducing a number semiconductor die that can be produced on a corresponding semiconductor wafer. Furthermore, previous image sensor packages can be susceptible to edge flare, e.g., unwanted light reaching the image sensor and/or tilt of the protective cover, which can adversely affect performance of the image sensor.

### SUMMARY

In a general aspect, a semiconductor package includes a semiconductor die having an image sensor disposed on a first surface. The package further includes a signal redistribution layer disposed on a second surface of the semiconductor die that is opposite the first surface. The package also includes at least one via extending through the semiconductor die from the first surface to the second surface, where a via of the at least one via electrically connects a signal trace on the first surface of the semiconductor die with the signal redistribution layer. The package also includes a glass cover coupled with a portion of the first surface of the semiconductor die via an attachment dam. The portion of the first surface excluding the image sensor, and the attachment dam and the glass cover define a sidewall that is orthogonal to the first surface of the semiconductor die.

In another general aspect, a semiconductor package includes a semiconductor die having an image sensor on a first surface of the semiconductor die. The semiconductor die includes a notch disposed around a perimeter of the first surface. The package further includes a signal redistribution layer disposed on a second surface of the semiconductor die opposite the first surface. The package also includes at least one via extending through the semiconductor die from the first surface to the second surface, where via of the at least one via electrically connects a signal trace on the first surface of the semiconductor die with the signal redistribution layer. The package also includes a glass cover coupled with a portion of the first surface of the semiconductor die via an attachment dam. The portion of the first surface excludes the image sensor. The attachment dam and the glass cover define a sidewall that is orthogonal to the first surface of the semiconductor die. The package also includes an encapsulant disposed on the sidewall and in the notch.

In another general aspect, a method for producing a semiconductor package includes forming a through-via from a first surface of a semiconductor die to second surface of a semiconductor die opposite the first surface, where the semiconductor die includes an image sensor on the first surface. The method also includes forming a signal redistribution layer on the second surface of the semiconductor die, where the conductive through-via electrically couples a signal trace included on the first surface of the semiconductor die with the signal redistribution layer. The method further includes forming a notch around at least a portion of a perimeter of the first surface of the semiconductor die. The method also include forming an attachment dam on a glass cover and coupling the attachment dam with a portion of the first surface of the semiconductor die excluding the image sensor, where the attachment dam and the glass cover define a sidewall that is orthogonal to the first surface of the semiconductor die The method still further includes disposing an encapsulant in the notch and on the sidewall.

### BRIEF DESCRIPTION OF THE DRAWINGS

FIG. 1 is a diagram illustrating an example chip-scale image sensor package.

FIGS. 2A and 2B are diagrams illustrating example chip-scale image sensor packages including a light-blocking mask.

FIG. 3 is a diagram illustrating an example chip-scale image sensor package with an alternative through-silicon via arrangement as compared with the chip-scale image sensor package of FIG. 1.

FIGS. 4A to 4H are diagrams illustrating an example process for preparing image sensor semiconductor die of a semiconductor wafer for inclusion in a chip-scale package.

FIGS. 5A to 5E are diagrams illustrating an example process for producing glass covers for chip-scale image sensor packages.

FIGS. 6A to 6H are diagrams illustrating an example process for producing a chip-scale image sensor package using the semiconductor wafer of FIGS. 4A to 4H and the protective covers of FIGS. 5A to 5E.

FIG. 7 is a flowchart illustrating an example method for implementing the process of FIGS. 4A to 4H.

FIG. 8 is a flowchart illustrating an example method for implementing the process of FIGS. 5A to 5E.

FIG. 9 is a flowchart illustrating an example method for implementing the process of FIGS. 6A to 6H.

### DETAILED DESCRIPTION

At least one technical problem associated with prior image sensor packages is susceptibility to environmental factors in at least some applications. For instance, image sensors used in automotive and/or industrial applications can be subjected to harsh operating environments. In such environments, prior image sensor packages can be exposed, for example, to high moisture levels, which can penetrate the package causing degradation of performance of the image sensor and/or failure of the image sensor. Such moisture penetration can result from insufficient edge protection in such packages. Further, such insufficient edge protection can allow for the occurrence of edge flare, where unwanted light reaches the image sensor, e.g., from sides of the package and/or due to reflection in the package. Such unwanted light can degrade performance of the corresponding image sensor.

Another technical problem with prior approaches is an amount of non-optically active area that is used for attachment of a protective cover, such as glass cover. and for wire bond connections with other package elements. The non-optically active area can be an area excluding optical elements of the image sensor, which can be referred to as a Keep Out Zone (KOZ). A KOZ of an image sensor semiconductor die can, at least partially, surround an optically active portion of an image sensor semiconductor die. That is, a KOZ can be disposed around a perimeter of an image sensor semiconductor die with an optically active area of the image sensor being bounded by the KOZ. In prior implementations, a KOZ is sized to account for application (dispensing) of dam material, such as a non-conductive adhesive, which is used to attach a corresponding protective cover, e.g., to protect the optically active portion of the image sensor from external factors. Due to process variations in such dispensing processes and/or an amount of dam material used, the KOZ is sized to account for this variation and/or a volume of dam material. A KOZ can also be sized to allow for placement of bond pads for attachment of wire bonds. In prior implementations, a resulting area of a KOZ can prevent reduction in an overall area (die size) of an image sensor semiconductor die, preventing increases in a number of total image sensor devices that can be produced on a given semiconductor wafer.

Still another technical problem with prior approaches is protective cover tilt, which can occur due to process variations, e.g., dam material thickness variation, width variation, etc., when dispensing dam material. As a result of such variations, a protective cover of an image sensor package can be tilted relative to a corresponding image sensor semiconductor die. That is, cover tilt results in a plane of a protective cover, after attachment of the cover, not being parallel, or substantially parallel, with a plane of a corresponding image sensor semiconductor die. Such tilt can affect transmission of light through the cover to the optically active elements of the image sensor, e.g., due to refraction, which can adversely affect performance of the image sensor.

One technical solution to at least some of the aforementioned technical problems can be the use of chip-scale packaging for an image sensor semiconductor die, where a pre-formed attachment dam is used for coupling a protective cover with the image sensor semiconductor die. Vias (e.g., through-vias) can be included through the image sensor semiconductor die to facilitate electrical connection of elements of the image sensor with a signal redistribution layer (RDL) disposed on an opposite side of the semiconductor die. Such chip-scale packages can include an encapsulant that is disposed on a sidewall defined by the protective cover and the attachment dam. Further, a notch (recess, etc.) can be defined around a perimeter of the image sensor semiconductor die, and the encapsulant can be further disposed in the notch.

At least one technical effect of the foregoing technical solution is improved process control of dimensions, e.g., height and width, of an attachment dam used to couple a protective cover with a corresponding image sensor semiconductor. One benefit of this technical effect is reduced area of a corresponding KOZ and, as result, reduced overall die size of an image sensor semiconductor die, which can facilitate increasing a number of image sensor semiconductor die that can be produced on a given semiconductor wafer. Another benefit of this technical effect is reduction or prevention of protective cover tilt, which can reduce or eliminate adverse effects on image sensor performance caused by such protective cover tilt.

At least another technical effect of the foregoing technical solution is improved edge protection of the chip-scale image sensor package, e.g., due to the encapsulant disposed on the sidewall defined by the protective cover and the attachment dam, and/or disposed in the notch formed on the perimeter of the image sensor semiconductor die. One benefit of this technical effect is the reduction or elimination of moisture penetration that can adversely affect performance of a corresponding image sensor. Another benefit of this technical effect is reduction or elimination of edge flare.

At least another technical effect of the foregoing technical solution, facilitated by use of through-vias, is elimination of wire bond connections in an image sensor package. One benefit of this technical effect is further reduction of image sensor semiconductor die size.

For purposes of illustration, the example implementations described herein are shown in the drawings as side views, which can be cross-sectional views. Such views are shown to illustrate structural elements of the described implementations, where such structural may be obscured, e.g., by an encapsulant or other elements, in non-sectioned views.

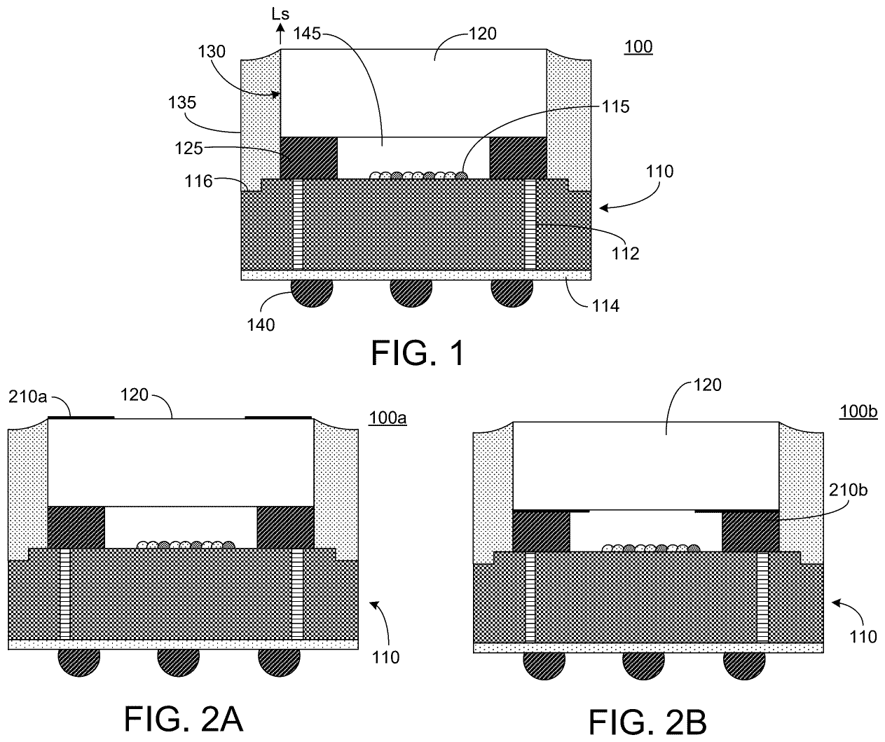

FIG. 1 is a diagram illustrating an example chip-scale image sensor package 100. The chip-scale image sensor package 100 includes an image sensor semiconductor die 110 that includes an optically active area 115 (image sensor elements) disposed on a first surface. The chip-scale image sensor package 100 further includes through-vias 112 that are formed through the image sensor semiconductor die 110, and a signal redistribution layer (RDL 114) that is disposed on a second surface of the image sensor semiconductor die 110 opposite the first surface. The through-vias 112 can electrically couple respective signal traces of the RDL 114 with corresponding signal traces disposed on the first surface of the image sensor semiconductor die 110, e.g., to electrically couple the RDL 114 with elements of the image sensor of the optically active area 115. As shown in FIG. 1, the chip-scale image sensor package 100 also includes solder bumps 140 that are disposed on the RDL 114, where the solder bumps 140 can facilitate electrical connection of the chip-scale image sensor package 100 with another device, such as image processor device (e.g., an application-specific integrated circuit).

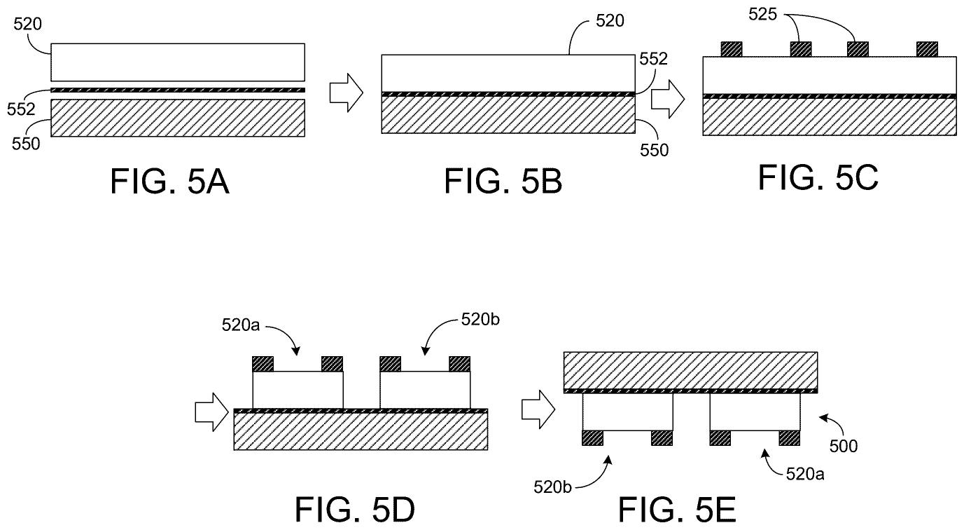

In this example, the chip-scale image sensor package 100 further includes a protective cover 120 (glass cover) that is coupled with the image sensor semiconductor die 110 via an attachment dam 125. In some implementations, the attachment dam 125 can be pre-formed on the protective cover 120 prior to coupling the protective cover 120 with the image sensor semiconductor die 110, such as in the example process of FIGS. 5A to 5E discussed below. Alternatively, the attachment dam 125 could be pre-formed on the image sensor semiconductor die 110 prior attachment of the protective cover 120 to the attachment dam 125. As shown in FIG. 1, the protective cover 120 and the attachment dam 125 define a sidewall 130 that is arranged along a line Ls that is orthogonal to the first surface of the image sensor semiconductor die 110. In some implementations, the attachment dam can include a dry film and/or a cured liquid material, such as photoresist that is patterned using photolithography processes.

In some implementations, the attachment dam 125 can be coupled with the image sensor semiconductor die 110 (and/or the protective cover 120) using a thin layer of non-conductive adhesive. In such approaches, the thin adhesive layer can have a well-controlled thickness and width, such that it does not result in cover tilt, or affect sizing of a corresponding KOZ of the image sensor semiconductor die 110. In some implementations, the thin layer of non-conductive adhesive can include a single material or a combination of two or more materials that are, e.g. layered. In some implementations, an adhesive layer can be omitted, e.g. for attachment dams including a dry film.

In this example, a cavity 145 (e.g., a hermetically sealed cavity) is defined by the first surface of the image sensor semiconductor die 110, the protective cover 120, and the attachment dam 125. In some implementations, a height of the attachment dam 125 can be such that an internal surface of the protective cover 120 is in contact with (e.g., is directly disposed on) the optically active area 115 of the image sensor semiconductor die 110. In this example, the through-vias 112 are disposed in the image sensor semiconductor die 110 such that they are below the attachment dam 125. As described herein, the location of through-vias relative to a corresponding attachment dam will depend on the particular implementation.

The image sensor semiconductor die 110 of the chip-scale image sensor package 100 also includes a notch 116 (a stair-shaped notch) that is disposed, at least partially, around a perimeter of the image sensor semiconductor die 110. The chip-scale image sensor package 100 further includes an encapsulant 135 (e.g., a liquid encapsulant, molding compound, etc.) that is disposed on the sidewall 130 and in the notch 116. In this example, the encapsulant 135 provides edge protection for the chip-scale image sensor package 100, where such edge protection can prevent moisture from penetrating into the cavity 145, reducing or eliminating adverse effects associated with such moisture penetration. Accordingly, the chip-scale image sensor package 100 can be used in applications for which prior image sensor packages are not well suited, such as automotive and/or industrial applications. Additionally the edge protection provided by the encapsulant 135 can reduce or prevent the occurrence of edge flare during operation of the chip-scale image sensor package 100.

FIGS. 2A and 2B are diagrams illustrating example chip-scale image sensor packages, respectively a chip-scale package 100a and a chip-scale package 100b, including respective light-blocking masks. In these examples, the chip-scale package 100a and the chip-scale package 100b each include the structure of the chip-scale image sensor package 100 of FIG. 1. Accordingly, for purposes of brevity, the details of the chip-scale image sensor package 100 discussed above are not repeated with respect to FIGS. 2A and 2B.

As shown in FIG. 2A, the chip-scale package 100a includes a light blocking mask 210a, that is disposed on an external surface of the protective cover 120, e.g., a surface facing away from the image sensor semiconductor die 110. In comparison, the chip-scale package 100b of FIG. 2B includes a light-blocking mask 210b which is disposed on internal surface of the protective cover 120, e.g., a surface facing the image sensor semiconductor die 110. In some implementations, light blocking masks can be included on both surfaces of a protective cover, e.g., an external surface and an internal surface.

In example implementations, a light-blocking mask, such as the light blocking mask 210a and the light-blocking mask 210b, can include an opaque (e.g., black film). For instance, an opaque film can be disposed on the protective cover 120 (or a glass wafer from which the protective cover 120 is formed), and that opaque film can be patterned using photolithography processes. Such light-blocking masks, e.g., in combination with edge protection provided by the encapsulant 135 of the chip-scale image sensor package 100, can reduce or prevent occurrence of edge flare in an image sensor package.

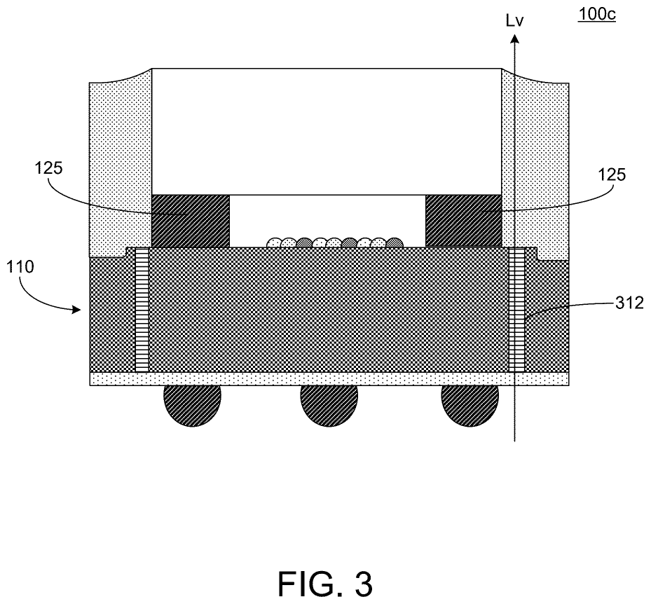

FIG. 3 is a diagram illustrating an example chip-scale image sensor package 100c with an alternative through-silicon via arrangement as compared with the chip-scale image sensor package 100 of FIG. 1. In this example, the structure of the chip-scale image sensor package 100c is similar to the structure of the chip-scale image sensor package 100 of FIG. 1. Accordingly, as with FIGS. 2A and 2B, for purposes of brevity, the details of the chip-scale image sensor package 100 discussed above are not repeated with respect to FIG. 3. As compared to the chip-scale image sensor package 100, through-vias 312 are formed in the image sensor semiconductor die 110, such that the through-vias 312 are not disposed beneath or under the attachment dam 125. That is, the through-vias 312 are located in a KOZ of the chip-scale image sensor package 100c such that, along a vertical line Lv through a through-via 312 does not intersect the attachment dam 125. The particular arrangement of through-vias in a chip-scale image sensor package can depend on a number of factors, which can include a size of a KOZ, layout of signal traces an RDL, and/or layout of signal trace on an active surface (image sensor surface) of an image sensor semiconductor die of the chip-scale package.

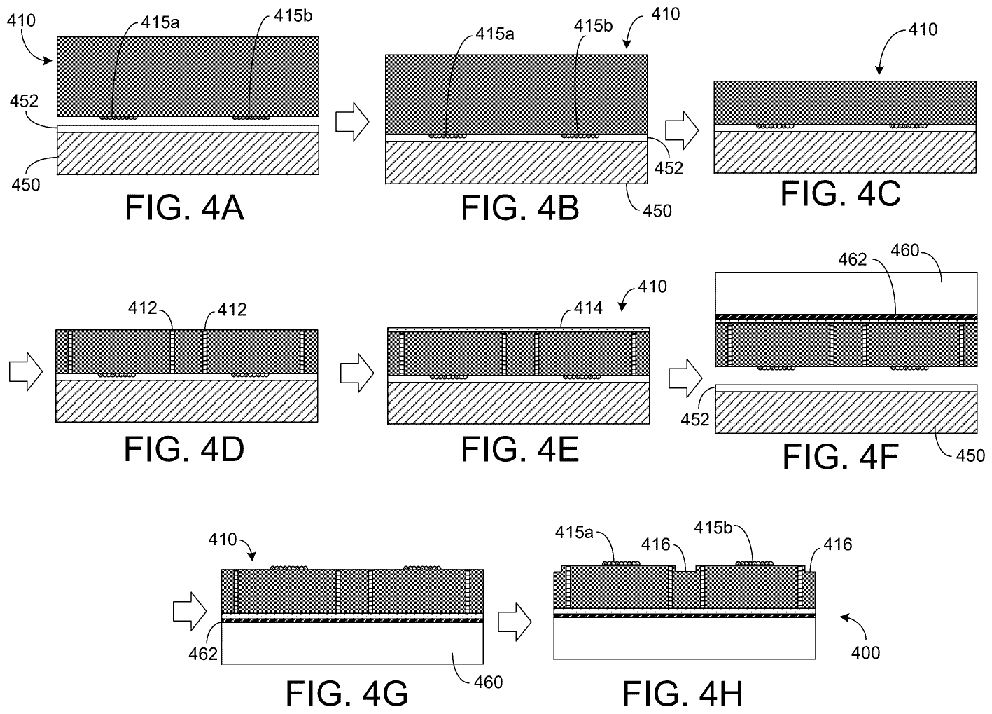

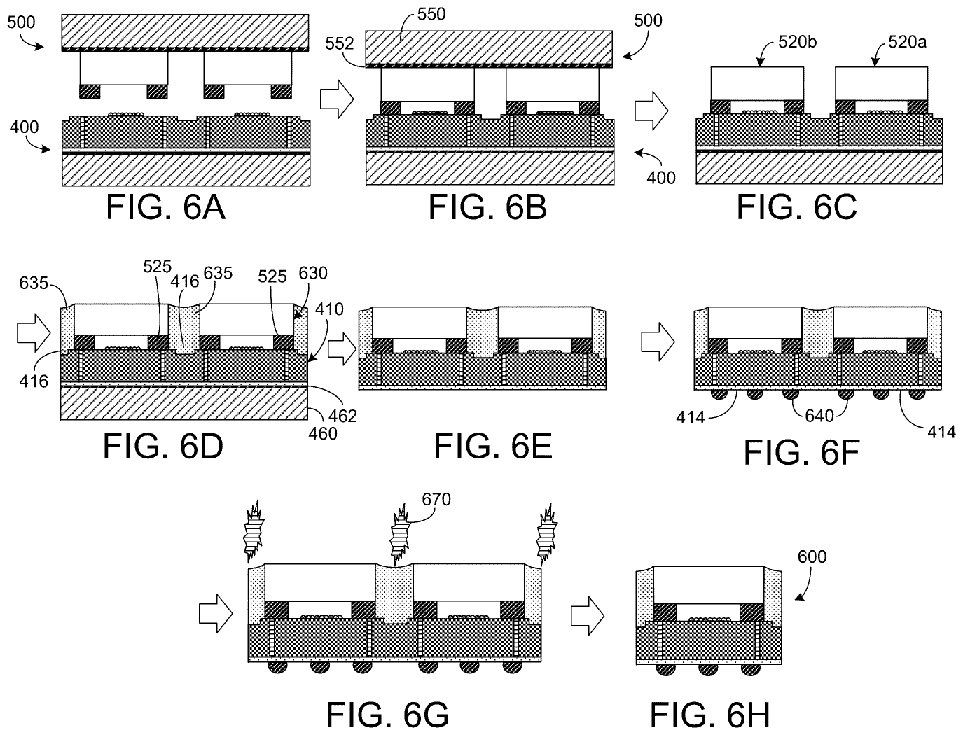

FIGS. 4A to 4G, 5A to 5E, and 6A-6H are diagrams illustrating example wafter level process flows that can be used to produce semiconductor, e.g., chip-scale, image sensor packages, such as the chip-scale image sensor package 100, the chip-scale package 100a, the chip-scale package 100b and the chip-scale image sensor package 100c of, respectively, FIGS. 1, 2A, 2B and 3. In some implementations, the process of FIGS. 4A to 4G, 5A to 5E, and 6A to 6H can be used to produce chip-scale packages having other configurations. For purposes of illustration, the wafer-level processes of 4A to 4G, 5A to 5E, and 6A-6H are illustrated for only two semiconductor devices of a semiconductor wafer 410 (FIG. 4A to 4H), two protective covers of a glass wafer (FIGS. 5A to 5E), and two corresponding chip-scale image sensor packages (FIGS. 6A to 6H). However, in some implementations, a single semiconductor wafer and a single corresponding glass wafter can be used to produce hundreds, or even thousands of semiconductor die (image sensor die), and protective (glass) covers, respectively, which can then be used to produce hundred to thousands of corresponding chip-scale image sensor packages. The processes of FIGS. 4A to 4G, 5A to 5E, and 6A-6H are given by way of example, In some implementations, other processes can be used to produce the example semiconductor packages described herein.

FIGS. 4A to 4H are diagrams illustrating a process for preparing image sensor semiconductor die of a semiconductor wafer 410 for inclusion in a chip-scale package. As shown in FIG. 4A, a semiconductor wafer 410 including an optical sensor 415a and an optical sensor 415b can be inverted for attachment to a temporary carrier 450, e.g., using a low-tack tape 452, such as a die-transfer tape. In this example, inverting the wafer refers to orienting the wafer such that the optical sensor 415a and the optical sensor 415b are downward facing in the view of FIG. 4A.

In FIG. 4B, the semiconductor wafer 410 has been coupled with the temporary carrier 450 via the low-tack tape 452. In FIG. 4C, the semiconductor wafer 410 has been thinned as compared to a thickness of the semiconductor wafer 410 as shown in FIGS. 4A and 4B. In some implementations, the wafer can be thinned to a thickness that is appropriate for a particular configuration of chip-scale packages in which each of the image sensor die of the semiconductor wafer 410 will be included. As shown in FIG. 4D, after thinning the wafer, through-vias 412 can be formed for facilitating respective electrical connections to the optical sensor 415a and the optical sensor 415b. After forming the through-vias 412, RDLs 414 for each of the image sensor semiconductor die are formed on the upward facing surface of the semiconductor wafer 410 as shown in FIG. 4E, which can be referred to as a backside of the semiconductor wafer 410. The RDLs 414 are electrically coupled with their respective optical sensors (optical sensor 415a and 415b) via the through-vias 412, as well as via signal traces disposed on the side of the semiconductor wafer 410 including the optical sensor 415a and the optical sensor 415b.

After forming the RDLs 414, as illustrated in FIG. 4F, a temporary carrier 460 can be coupled with the backside of the semiconductor wafer 410 via a low-tack tape 462, e.g., the temporary carrier 460 can be a wafer carrier that is coupled to the semiconductor wafer 410 using a die transfer tape. As also illustrated in FIG. 4F, the temporary carrier 450 and the low-tack tape 452 are removed from the downward facing surface of the semiconductor wafer 410, which can be referred to as a front-side, active side, optically-active side of the semiconductor wafer 410, and so forth.

After removing the temporary carrier 450 and the low-tack tape 452, the semiconductor wafer 410, the temporary carrier 460 and the low-tack tape 462 can be inverted (FIG. 4G) and notches 416 can be formed, at least partially, around a perimeter of each of the respective semiconductor die including the optical sensor 415a and the optical sensor 415b (FIG. 4H). As described herein, the notches 416 can facilitate edge protection when they are filled with encapsulant in a chip-scale package, such as the examples of FIGS. 1, 2A, 2B and 3. In some implementations, the notches 416 can be formed in the semiconductor wafer 410 using one or more of plasma etching, wet etching, dry etching, mechanical sawing, and/or laser sawing. While not specifically shown in FIG. 4H, in some implementations, a protective layer (e.g., photoresist or other material) can be disposed on the front side of the semiconductor wafer 410 during formation of the notches 416. That protective layer can then be removed after the notches 416 are formed. In the example, the semiconductor wafer 410, the temporary carrier 460 and the low-tack tape 462, as shown in FIG. 4H (referenced as wafer stack 400 in FIG. 4H) can be attaching with protective covers formed form a glass wafer, such the structure produced by the process of FIGS. 5A to 5E, which is described below.

FIGS. 5A to 5E are diagrams illustrating an example process for producing glass covers for chip-scale image sensor packages, such as in the example implementations described herein. As shown in FIG. 5A and 5B, a glass wafer 520 can be attached to a temporary carrier 550, e.g., using a low-tack tape 552, such as a die-transfer tape.

As illustrated in FIG. 5C, attachment dams 525 can be formed for respective protective covers that will be formed from the glass wafer 520. Depending on the particular implementation, the attachment dams 525 can formed using a number of different approaches. In some implementations., a dry film of uniform thickness can be coupled with (e.g., laminated to) the glass wafer 520. That dry film can then be patterned using photolithography and/or etch processes to the form the attachment dams 525 with uniform widths. In some implementations, a coating of photoresist (of uniform thickness) can be disposed on (spun on) the glass wafer 520. That coating of photoresist can then be patterned using photolithography processes to form the attachment dams 525 (with uniform widths). These approaches provide the benefit of KOZ reduction for image sensor semiconductor die, as described herein.

As shown in FIG. 5D, after forming the attachment dams 525, individual protective covers 520a and 520b, with the pre-formed glass attachment dams, can be formed from the glass wafer 520. In some implementations, forming the individual protective covers 520a and 520b from the glass wafer 520 can be accomplished using one or more of mechanical sawing, laser sawing, plasma etching, and/or wet etching. After forming the individual protective covers 520a and 520b, the temporary carrier 550, the low-tack tape 552 and the protective covers (referenced as a cover stack 500 in FIG. 5E) can be inverted, as shown in FIG. 5E in preparation for wafer-to-wafer bonding (attachment, coupling, etc.) with the semiconductor wafer 410 of FIGS. 4A to 4H. In some implementations, the attachment dams 525 could, instead, be formed on the semiconductor wafer 410 as part of the process of FIGS. 4A to 4H. Those attachment dams could them be coupled with individual protective covers formed from the glass wafer 520 (without attachment dams being formed on the glass wafer 520).

FIGS. 6A to 6H are diagrams illustrating an example process for producing a chip-scale image sensor package using the wafer stack 400 of FIG. 4H and the cover stack 500 of FIG. 5E. As shown in FIG. 6A, the cover stack 500 is positioned over the wafer stack 400 and, as shown in FIG. 6B, the cover stack 500 is then coupled with (wafer-to-wafer bonded with) the wafer stack 400 using, e.g., a non-conductive epoxy. As shown in FIG. 6C, the temporary carrier 550 and the low-tack tape 552 is then removed from the protective covers 520a and 520b. As shown in FIG. 6C, an encapsulant 635 is then disposed in the spaces between individual chip-scale image sensor packages of this example, where the encapsulant is disposed on respective sidewalls 630 defined by the protective covers 520a and 520a with pre-formed attachment dams, as well as in the notches 416.

As shown in FIG. 6E, after applying the encapsulant 635, the temporary carrier 460 and the low-tack tape 462 are removed from the backside of the semiconductor wafer 410 and, as shown in FIG. 6F, respective solder bumps 640 are formed on the RDLs 414. After forming the solder bumps as shown in FIG. 6G, in this example, the structure of FIG. 6F is cut, e.g., using a cutting tool 670, to singulate the combination of the wafer stack 400 coupled the cover stack 500, as well as the encapsulant 635, into individual, solder-bumped, chip-scale image sensor packages 600, as shown in FIG. 6H. The process of separating (singulating) individual chip-scale image sensor packages 600 with the cutting tool 670 can be performed from other side of the structures shown in FIGS. 6F and 6G, and can be accomplished using approaches described herein, e.g., mechanical sawing, laser sawing, plasma etching, and/or wet etching.

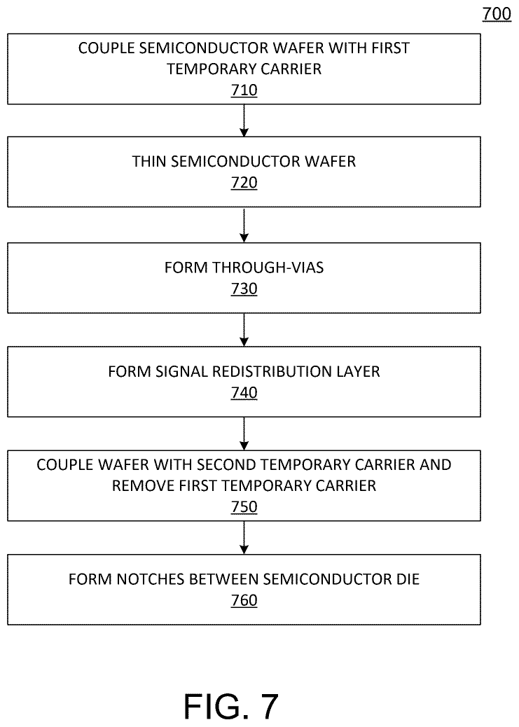

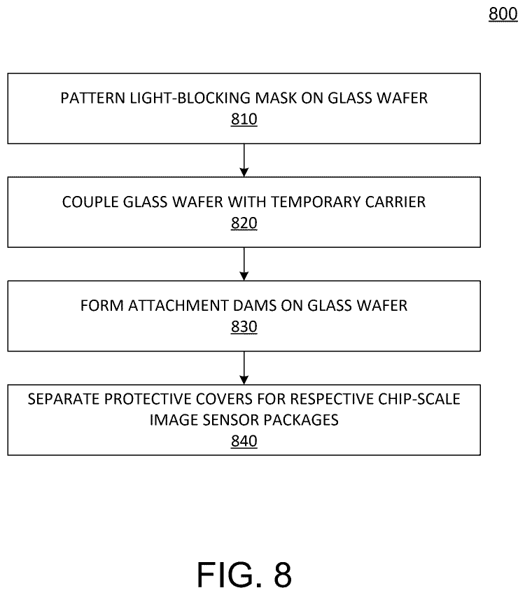

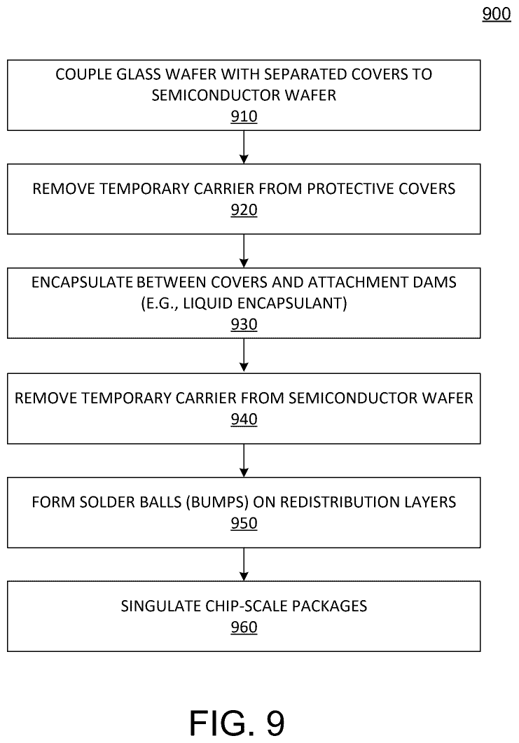

FIG. 7 is a flowchart illustrating an example method 700, which can implement the process of FIGS. 4A to 4H. At operation 710, the method 700 includes coupling a semiconductor wafer with a first temporary carrier. For instance, a semiconductor wafer including a plurality of image sensor semiconductor die can be coupled with a wafer carrier such that optically active surfaces of the image sensors are disposed, e.g., directly disposed, on the wafer carrier. At operation 720, the method 700 includes thinning the semiconductor wafer, e.g., backside grinding the wafer. In some implementations, other process can be used for thinning the semiconductor wafer, such as wet etching, dry etching, chemical-mechanical etching, etc. At operation 730, the method 700 includes forming through-vias of the plurality of semiconductor die of the wafer. At operation 740, the method 700 includes forming signal RDLs of the semiconductor die, e.g., on the backside. As described herein, the through-vias formed at operation 730 can interconnect respective signal traces of the RDLs with respective signal traces on the active surfaces of the semiconductor die, e.g., to electrically couple the RDLs with corresponding elements of the image sensors. At operation 750, the method 700 includes coupling the semiconductor wafer, e.g., a backside surface including the RDLs, with a second temporary carrier and removing the first temporary carrier. At operation 760, the method 700 includes forming notches, such as described herein, between image sensor semiconductor die. The resulting wafer produced by the method 700 and the second temporary carrier can then be combined with a glass cover wafer produced by the process of FIGS. 5A to 5E (and/or the method of FIG. 8), such as using the process of FIGS. 6A to 6H (and/or the method of FIG. 9).

FIG. 8 is flowchart illustrating an example method 800, which can implement the process of FIGS. 5A to 5E. As shown in FIG. 8, at operation 810, the method 800 includes patterning light-blocking masks of protective covers for a plurality of image sensor semiconductor die on a glass wafer. In some implementations, the operation 810 can be omitted to produce protective covers without light-blocking masks. At operation 820, the method 800 includes coupling the glass wafer with a temporary carrier, e.g., a wafer carrier. In the example of FIG. 8, the glass wafer can be coupled with the temporary carrier such that a surface of the glass wafer including the light-blocking masks is disposed, e.g., directly disposed, on the temporary carrier, or such that a surface of the of the wafer without the light-blocking masks is disposed, e.g., directly disposed, on the temporary carrier. The surface of the glass wafer disposed on the temporary carrier at operation 820 will depend on the particular implementation, e.g., whether the light-blocking masks will be on respective exposed surfaces the protective covers, or surfaces of the protective covers on which attachment dams are formed.

At operation 830, the method 800 includes forming attachment dams of respective protective covers. As described herein, in some implementations, attachment dams can be formed using a dry film, lamination and/or photolithography processes. At operation 840, the method 800 includes separating the glass wafer into individual protective covers with respective attachment dams. As described herein, in some implementations, separation of the glass wafer into individual protective covers can include mechanical sawing, laser sawing, plasma etching, and/or wet etching. The resulting separated protective covers of the glass wafer produced by the method 800 and the corresponding temporary carrier can then be combined, e.g., via wafer-to-wafer bonding, with the semiconductor wafer produced by the process of FIGS. 4A to 4H (and/or the method of FIG. 7).

FIG. 9 is a flowchart illustrating an example method 900 for implementing the process of FIGS. 6A to 6H. In this example, the method 900 can be implemented using a semiconductor wafer produced by the method 700 (and/or the process of FIGS. 4A to 4H) and protective covers produces by the method 800 (and/or the process of FIGS. 5A to 5E) to produce a plurality of chip-scale image sensor device packages, such as the devices of FIGS. 1, 2A, 2B and/or 3. At operation 910, the method 900 includes coupling the glass wafer with separated covers with the semiconductor wafer, e.g., via wafer-to-wafer bonding. That is, respective attachment dams of the separate protective covers can be coupled with respective KOZs of image sensor devices included on the semiconductor wafer. At operation 920, the method 900 includes removing the temporary carrier of the method 800 from the separated protective covers. At operation 930, the method 900 includes disposing encapsulant between the glass covers and attachments dams of the image sensor devices, such that the encapsulant is disposed on respective sidewalls defined by the glass covers and attachments dams. In this example, the operation 930 further includes disposing the encapsulant in the notches formed at operation 760 of the method 700.

At operation 940 of the method 900, the second temporary carrier is removed from the semiconductor wafer. At opearation 950 of the method 900, solder bumps are formed on the respective RDLs of the semiconductor wafer. At operation 960, the method 900 includes singulating chip-scale image sensor packages from the combined semiconductor wafer and protective cover (glass) wafer. Singulation can be performed, e.g., through the encapsulant and the semiconductor wafer, from either side of the chip-scale image packages, e.g., from the protective cover side or from the RDL side. As described herein, in some implementations singulation can be performed using one or more wafer sawing processes, e.g., mechanical sawing, laser cutting, plasma etching, etc.

In a general aspect, a chip-scale package includes a semiconductor die having an image sensor disposed on a first surface. The package further includes a signal redistribution layer disposed on a second surface of the semiconductor die that is opposite the first surface. The package also includes at least one via extending through the semiconductor die from the first surface to the second surface, where a via of the at least one via electrically connects a signal trace on the first surface of the semiconductor die with the signal redistribution layer. The package also includes a glass cover coupled with a portion of the first surface of the semiconductor die via an attachment dam. The portion of the first surface excluding the image sensor, and the attachment dam and the glass cover define a sidewall that is orthogonal to the first surface of the semiconductor die.

Implementations can include one or more of the following features or aspects, alone or in combination. For example, the chip-scale package can include an encapsulant disposed on the sidewall. The chip-scale package can include a notch disposed around at least a portion of a perimeter of the first surface of the semiconductor die. The encapsulant can be further disposed in the notch. The notch can be stair-shaped. The encapsulant can include a liquid encapsulant material.

The attachment dam can include a dry film. The attachment dam can include photoresist. The chip-scale package can include an adhesive coupling the attachment dam with the first surface of the semiconductor die. The chip-scale package can include an adhesive coupling the attachment dam with the glass cover.

The via can be at least partially disposed under the attachment dam.

The chip-scale package can include at least one solder bump disposed on the signal redistribution layer.

The chip-scale package can include a light-blocking mask disposed on a portion of the glass cover that is vertically above the portion of the first surface of the semiconductor die excluding the image sensor.

The glass cover can be coupled with the first surface of the semiconductor die such that a cavity is formed between the image sensor and the glass cover.

In another general aspect, a chip-scale package includes a semiconductor die having an image sensor on a first surface of the semiconductor die. The semiconductor die includes a notch disposed around a perimeter of the first surface. The package further includes a signal redistribution layer disposed on a second surface of the semiconductor die opposite the first surface. The package also includes at least one via extending through the semiconductor die from the first surface to the second surface, where via of the at least one via electrically connects a signal trace on the first surface of the semiconductor die with the signal redistribution layer. The package also includes a glass cover coupled with a portion of the first surface of the semiconductor die via an attachment dam. The portion of the first surface excludes the image sensor. The attachment dam and the glass cover define a sidewall that is orthogonal to the first surface of the semiconductor die. The package also includes an encapsulant disposed on the sidewall and in the notch.

Implementations can include one or more of the following features or aspects, alone or in combination. For example, the chip-scale package can include an adhesive coupling the attachment dam with the first surface of the semiconductor die. The chip-scale package can include an adhesive coupling the attachment dam with the glass cover.

The via can be at least partially disposed under the attachment dam.

The chip-scale package can include at least one solder bump disposed on the signal redistribution layer.

The chip-scale package can include a light-blocking mask disposed on a portion of the glass cover that is vertically above the portion of the first surface of the semiconductor die excluding the image sensor.

The glass cover can be coupled with the first surface of the semiconductor die such that a cavity is formed between the image sensor and the glass cover.

In another general aspect, a method for producing a chip-scale package includes forming a through-via from a first surface of a semiconductor die to second surface of a semiconductor die opposite the first surface, where the semiconductor die includes an image sensor on the first surface. The method also includes forming a signal redistribution layer on the second surface of the semiconductor die, where the conductive through-via electrically couples a signal trace included on the first surface of the semiconductor die with the signal redistribution layer. The method further includes forming a notch around at least a portion of a perimeter of the first surface of the semiconductor die. The method also include forming an attachment dam on a glass cover and coupling the attachment dam with a portion of the first surface of the semiconductor die excluding the image sensor, where the attachment dam and the glass cover define a sidewall that is orthogonal to the first surface of the semiconductor die The method still further includes disposing an encapsulant in the notch and on the sidewall.

Implementations can include one or more of the following features or aspects, alone or in combination. For example, the method can be performed on a wafer-scale. The method can include forming at least one solder bump on the signal redistribution layer. The method can include singulating the chip-scale package from a plurality of other chip-scale packages.

A number of implementations have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some implementations may be implemented using various types of semiconductor processing technologies associated with semiconductor substrates including, but not limited to, for example, silicon (Si), gallium arsenide (GaAs), silicon carbide (SiC), gallium nitride (GaN), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic and/or process flows depicted in the figures do not require the particular order shown, or sequential order, to achieve desirable results. In addition, other operations may be included, or operations may be eliminated, from the described flows, and other components or elements may be added to, or removed from the described devices, methods and/or systems. Accordingly, other implementations are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. A semiconductor package comprising:
a semiconductor die including an image sensor, the image sensor being disposed on a first surface of the semiconductor die;
a signal redistribution layer disposed on a second surface of the semiconductor die, the second surface being opposite the first surface;
at least one via extending through the semiconductor die from the first surface to the second surface, a via of the at least one via electrically connecting a signal trace on the first surface of the semiconductor die with the signal redistribution layer; and
a glass cover coupled with a portion of the first surface of the semiconductor die via an attachment dam, the portion of the first surface excluding the image sensor, and the attachment dam and the glass cover defining a sidewall that is orthogonal to the first surface of the semiconductor die.

2. The semiconductor package of claim 1, further comprises an encapsulant disposed on the sidewall.

3. The semiconductor package of claim 2, a notch disposed around at least a portion of a perimeter of the first surface of the semiconductor die, the encapsulant being further disposed in the notch.

4. The semiconductor package of claim 3, wherein the notch is stair-shaped.

5. The semiconductor package of claim 2, wherein the encapsulant includes a liquid encapsulant material.

6. The semiconductor package of claim 1, wherein the attachment dam includes a dry film.

7. The semiconductor package of claim 1, wherein the attachment dam includes photoresist.

8. The semiconductor package of claim 1, further comprising an adhesive coupling the attachment dam with the first surface of the semiconductor die.

9. The semiconductor package of claim 1, further comprising an adhesive coupling the attachment dam with the glass cover.

10. The semiconductor package of claim 1, wherein the via is at least partially disposed under the attachment dam.

11. The semiconductor package of claim 1, further comprising at least one solder bump disposed on the signal redistribution layer.

12. The semiconductor package of claim 1, further comprising a light-blocking mask disposed on a portion of the glass cover that is vertically above the portion of the first surface of the semiconductor die excluding the image sensor.

13. The semiconductor package of claim 1, where the glass cover is coupled with the first surface of the semiconductor die such that a cavity is formed between the image sensor and the glass cover.

14. A semiconductor package comprising:
a semiconductor die including an image sensor, the image sensor being disposed on a first surface of the semiconductor die, the semiconductor die having a notch disposed around a perimeter of the first surface;
a signal redistribution layer disposed on a second surface of the semiconductor die, the second surface being opposite the first surface;
at least one via extending through the semiconductor die from the first surface to the second surface, a via of the at least one via electrically connecting a signal trace on the first surface of the semiconductor die with the signal redistribution layer; and
a glass cover coupled with a portion of the first surface of the semiconductor die via an attachment dam, the portion of the first surface excluding the image sensor, and the attachment dam and the glass cover defining a sidewall that is orthogonal to the first surface of the semiconductor die;
an encapsulant disposed on the sidewall and in the notch.

15. The semiconductor package of claim 14, further comprising an adhesive coupling the attachment dam with the first surface of the semiconductor die.

16. The semiconductor package of claim 14, further comprising an adhesive coupling the attachment dam with the glass cover.

17. The semiconductor package of claim 14, wherein the via is at least partially disposed under the attachment dam.

18. The semiconductor package of claim 14, further comprising at least one solder bump disposed on the signal redistribution layer.

19. The semiconductor package of claim 14, further comprising a light-blocking mask disposed on a portion of the glass cover that is vertically above the portion of the first surface of the semiconductor die excluding the image sensor.

20. The semiconductor package of claim 14, where the glass cover is coupled with the first surface of the semiconductor die such that a cavity is formed between the image sensor and the glass cover.

21. A method for producing a semiconductor package, the method comprising:
forming a through-via from a first surface of a semiconductor die to second surface of a semiconductor die opposite the first surface, the semiconductor die including an image sensor on the first surface;
forming a signal redistribution layer on the second surface of the semiconductor die, the through-via electrically coupling a signal trace included on the first surface of the semiconductor die with the signal redistribution layer;
forming a notch around at least a portion of a perimeter of the first surface of the semiconductor die;
forming an attachment dam on a glass cover;
coupling the attachment dam with a portion of the first surface of the semiconductor die excluding the image sensor the attachment dam and the glass cover defining a sidewall that is orthogonal to the first surface of the semiconductor die; and
disposing an encapsulant in the notch and on the sidewall.

22. The method of claim 21, wherein the method is performed on a wafer-scale.

23. The method of claim 22, further comprising:
forming at least one solder bump on the signal redistribution layer; and
singulating the semiconductor package from a plurality of other semiconductor packages.
